(19) United States
(12) Patent Application Publication
(10) Pub. No.: US 2002/0060360 A1
(43) Pub. Date: May 23, 2002

(54) Integrated fluid supply apparatus, sealing device used there, and semiconductor manufacturing system using it

(76) Inventors: Kazuhiko Sugiyama, Nirasaki-Shi (JP); Shuji Moriya, Nirasaki-Shi (JP)

Correspondence Address: PILLSBURY WINTHROP, LLP, P.O. BOX 10500, MCLEAN, VA, 22102, US

(21) Appl. No.: 09/983,014

(22) Filed: Oct. 22, 2001

(30) Foreign Application Priority Data
Oct. 23, 2000 (JP) 2000-323057

(51) Int. Cl. H01L 21/44; H01L 23/20

(52) U.S. Cl. 257/682; 438/115; 257/687

(57) ABSTRACT

A sealing device to be inserted between a unit-side connection surface and a block-side connection surface, and providing a sealing performance therebetween, includes a first connection surface configured to be suitable to a first sealing feature of the unit-side connection surface, and a second connection surface configured to be suitable to a second sealing feature of the block-side connection surface. The first sealing feature being different from the second sealing feature.

### BACKGROUND OF THE INVENTION

1. Field of the Invention

The present invention relates to an integrated fluid supply apparatus, a sealing device used therein, and a semiconductor manufacturing system employing it, and, in particular, to an integrated fluid supply apparatus, a sealing device used therein, and a semiconductor manufacturing system employing it in which a plurality of fluid processing units are connected by flow path blocks which passe the fluid.

2. Description of the Related Art

For example, a semiconductor manufacturing system needs a high-purity semiconductor manufacture gas, career gas, etc. (generically referred to as ‘a semiconductor manufacture gas’, hereinafter) to be supplied, and the semiconductor manufacture gas is supplied to the semiconductor manufacturing system through a gas supply apparatus.

Moreover, in recent years, a semiconductor manufacturing system tends to shift to a single wafer type from a batch type, to carry out simultaneous drive of many chambers, and thus, improve the productivity for semiconductor devices. In such a system, since it is necessary to supply a high-purity gas to each chamber of the system, a gas supply apparatus therefor becomes complicated.

Thereby, if a gas supply apparatus is such that gas processing units (mass flow controller, filter, etc.) are connected by using joints, pipes, sealing devices, etc. according to a conventional style, the gas supply apparatus and thereby also the semiconductor manufacturing system itself should be large-sized, and, thereby, effective use of a clean room becomes not possible. Furthermore, in recent years, as semiconductor devices to be manufactured come to have very fine and complicated configurations, fine flow control of the semiconductor manufacture gas and improvement in gas substitution performance have been demanded therefor.

Therefore, in order to cope with such various requests, it is necessary to attain a miniaturization of a gas supply apparatus, and, for this reason, the gas supply apparatus should be unified or be in a form of a unit (a unified gas supply apparatus will be referred to as an integrated gas supply apparatus, hereinafter). This integrated gas supply apparatus includes gas processing units (including a mass flow controller, a filter, etc.) located in an upper part, and base blocks arranged at a lower part of these gas processing units, in general.

Furthermore, in the gas supply apparatus, connection mouths through which the semiconductor manufacture gas flows in/flows out are provided in a bottom surface. The base blocks have gas passages provided inside, and have connection mouths provided at the top surface on each of both ends thereof. These gas processing units are disposed in sequence with similar gas processing units in a row in an order of processes to be provided on the semiconductor manufacture gas. The base blocks have a function of connecting the unit with an adjacent unit in the series of the gas processing units.

Specifically, in a case where a mass flow controller and a filter as the gas processing units are connected adjacently, these mass flow controller and filter are connected by the base block. Under this condition, connection is made between a gas outflow connection mouth of the mass flow controller and one connection mouth of the base block, while connection is made between the other connection mouth of the base block and a gas inflow connection mouth of the filter. Thereby, a flow rate controlled gas from the mass flow control is supplied to the filter through the base block, and thus, fine particles in the semiconductor manufacture gas are removed by the filter.

In order to prevent that the semiconductor manufacture gas from leaking at the connection position between the gas processing unit and the base block, a sealing device is disposed between the connection mouth of the gas processing unit and the connection mouth of the base block. In the related art, as for the sealing device used for the integrated gas supply apparatus, two types thereof, i.e., a metal gasket and a metal C ring, are used.

FIG. 1 shows a state where a base block 2 is connected with a gas processing unit 1 using a metal gasket 10, and FIG. 2 shows a state where a base block 2 is connected with a gas processing unit 1 but using a metal C ring 11.

As shown in FIG. 1, as for the gas processing unit 1 suitable for the metal gasket 10, a projection 5 is provided on a sealing surface 4 of the unit 1 for the sealing purpose. Moreover, the base block 2 suitable for the metal gasket 10 also has a projection 9 provided on a sealing surface 8 thereof for the same purpose.

When the base block 2 is connected with the gas processing unit 1, after inserting the metal gasket 10 between the sealing surface 4 of the device 1 and the sealing surface 8 of the base block 2, the gas processing unit 1 and the base block 2 are fixed to one another. The metal gasket 10 is made of metal and has an annular plate-like shape. The metal gasket 10 has thus a ring-like shape as a gas passing hole 12 through which the semiconductor manufacture gas passes is provided at the center thereof.

This metal gasket 10 enters a state where it is inserted between the sealing surface 4 and the sealing surface 8 of the unit 1 and base block 2, when the gas processing unit 1 is fixed with the base block 2. Under this condition, the projection 5 on the unit side and the projection 9 on the block side both stick into the metal gasket 10, as shown in FIG. 1.

Thereby, sealing is positively made between the unit-side sealing surface 4 and the metal gasket 10, and between the block-side sealing surface 8 and the metal gasket 10, and, thereby, the semiconductor manufacture gas is prevented from leaking from the connection position between the gas processing unit 1 and the base block 2.

On the other hand, as shown in FIG. 2, the gas processing unit 1 and the base block 2 suitable for the metal C ring 11 has flat surfaces both on the unit-side sealing surface 4 and the block-side sealing surface 8. When the base block 2 is connected with the gas processing unit 1, after inserting the metal C ring 11 between the unit-side sealing surface 4 and the block-side sealing surface 8, the gas processing unit 1 and the base block 2 are fixed to one another.

The metal C ring 11 is also an annular member made of metal, and has a configuration such as to have an elastic property as a result of a hollow structure (like a circularly curved pipe) thereof and a slit 14 being provided on the outer surface thereof. Moreover, in the state in which the unit 1 and base block 2 are fixed to one another, the semiconductor manufacture gas passes through a gas passing hole 13 provided at the center thereof.

This metal C ring 11 is inserted between the unit-side sealing surface 4 and the block-side sealing surface 8, when the gas processing unit 1 and the base block 2 are fixed to one another. Under this condition, by being compressed between the unit-side sealing surface 4 and the block-side sealing surface 8, the metal C ring 11 is deformed elastically, and thus presses the unit-side sealing surface 4 and the block-side sealing surface 8 as the reaction thereto.

The metal C ring 11 is thus stuck to both the unit-side sealing surface 4 and the block-side sealing surface 8 due to this pressing force, and sealing between the unit-side sealing surface 4 and the metal C ring 11 and sealing between the block-side sealing surface 8 and the metal C ring 11 are thus ensured. Thereby, the semiconductor manufacture gas is prevented from leaking from the connection position between the gas processing unit 1 and the base block 2.

The gas processing units and the base blocks of the integrated gas supply apparatus suitable for the metal gasket have a problem in that they cannot be used together with the gas processing units and the base blocks of the integrated gas supply apparatus suitable for the metal C ring. That is, if, for example, the suitable sealing devices differ in configuration from one another between the gas processing units suitable for the metal C ring and the base blocks suitable for the metal gasket, this combination cannot be properly realized in the standpoint of proper sealing performance.

For this reason, it is necessary to use together the gas processing units and the base blocks having the same sealing feature (suitable for the same type of sealing device), thereby, there is no sufficient flexibility in selection of gas processing units and base blocks, and thus, there is a problem in that the performance may be degraded and/or the cost may rise in the resulting integrated gas supply apparatus.

This is because, even in a case where, for example, there are a mass flow controller and a filter both high-precision or inexpensive as gas processing units for an integrated gas supply apparatus, when the sealing feature (configuration) thereof differ from one another, it is necessary to select another component which may not have such a high precision or may not be so inexpensive but meets the sealing feature condition, for providing a proper sealing performance.

### SUMMARY OF THE INVENTION

The present invention has been devised in consideration of such a problem, and an object of the present invention is to provide an integrated fluid supply apparatus in which a fluid processing unit and a flow path block having different sealing features can be properly connected, a sealing device which can achieve this apparatus, and a semiconductor manufacturing system employing it.

An integrated fluid supply apparatus according to the present invention includes:

fluid processing units each performing predetermined processing on a fluid supplied via a unit-side fluid connection mouth provided in a unit-side connection surface thereof;

a flow path block having block-side connection mouths on block-side connection surfaces thereof to be connected with the unit-side connection mouths, and, as being disposed below the fluid processing units, communicating the unit-side fluid connection mouths of the adjacent fluid processing units; and

sealing devices each inserted between the unit-side connection mouth and the block-side connection mouth, and, thus, performing sealing between the unit-side connection surface and the block-side connection surface at a connection position therebetween;

wherein at least on of the sealing devices comprises a first connection surface configured to be suitable to a first sealing feature of the unit-side connection surface and a second connection surface configured to be suitable to a second sealing feature of the block-side connection surface, the first sealing feature being different from the second sealing feature.

The first sealing feature may be of a metal gasket, while the second sealing feature may be of a metal C ring.

At least the block-side connection surface and the second connection surface may be preferably configured such that connection therebetween be in an effective area contact.

According to the present invention described above, the adjacent fluid processing apparatuses are communicated with one another by the flow path block, and thereby, the fluid passes through the respective fluid processing apparatuses and predetermined processing is performed on the fluid thereby. When the fluid processing apparatus and flow path block are connected, the sealing device is inserted between the unit-side fluid connection mouth provided in the fluid processing apparatus and the block-side connection mouth provided in the flow path block. Thereby, the connection position therebetween is sealed so that the fluid may pass through the sealing device bat may not leak outside thereof.

In the related art, a sealing feature of such a fluid processing apparatus and a sealing feature of such a flow path block should be the same as one another. Accordingly, a sealing device should be selected as being suitable to this sealing feature. However, when a sealing feature of a fluid processing apparatus and a sealing feature of a flow path block differ from one another, such a sealing device as that having a pair of connection surfaces both having the same sealing feature cannot be applied to the connection position therebetween.

According to the present invention, a sealing device has a first connection surface suitable to a sealing feature of an unit-side connection surface, and a second connection surface suitable to a different sealing feature of a block-side connection surface. Therefore, even when the sealing feature of the fluid processing equipment and the sealing feature of the flow path block differ from one another, it is possible to connect the flow path block with the fluid processing apparatus by the sealing device properly, that is, the sealing device according to the present invention can provide a sufficient sealing performance at the connection position between these types of flow path block and fluid processing unit. Thereby, it is possible to freely selecting a combination between a fluid processing unit and a flow path block, and, thus, raise in performance of a resulting integrated fluid supply apparatus, which is a complete collection of various kinds of such fluid processing apparatuses prepared for a predetermined purpose, and also, cost reduction thereof can be attained.

For example, in a case where the unit-side connection surface has a sealing feature of a metal gasket such as that mentioned above (having a projection), while the block-side connection surface has a sealing feature suitable to a metal C ring such as that mentioned above (having a simple flat surface), a sealing device according to the present invention may have a first connection surface configured to be suitable for the sealing feature of the metal gasket to be connected with the unit-side fluid connection surface, and a second connection surface configured to be suitable to the sealing feature of the metal C ring to be connected with the block-side connection surface. Thereby, it is possible to positively connect the fluid processing apparatus having the sealing feature for the metal gasket with the flow path block having the sealing feature for the metal C ring properly providing a sufficient sealing performance at the connection position therebetween.

It is almost the case that such metal gaskets or such metal C rings are applied as sealing devices in an integrated fluid supply apparatus, in the related art. Accordingly, sealing devices according to the present invention may be applied to almost all types of such integrated fluid supply apparatuses, which may be used together with the metal gaskets and/or metal C rings.

Moreover, by configuring the block-side connection surface and the second connection surface such that a contact style therebetween be in an effective area contact, the sealing area increases effectively and, therefore, can aim at improvement in the sealing performance at the connection position therebetween.

Thus, according to the present invention, it is possible to provide a sealing device which is used for connecting units/components/parts together even having different sealing features, for example, for connecting a fluid processing unit suitable to a metal gasket with a flow path block suitable to a metal C ring. Thereby, in an integrated fluid supply apparatus, the metal gaskets may be used for sealing at connection between parts/components all suitable to the metal gasket, the metal C rings may be used for sealing at connection between parts/components all suitable to the metal C ring, and, also, the sealing devices according to the present invention may be used for sealing at connection between parts/components including ones suitable for the metal gasket and others suitable to the metal C ring. Thus, by applying the present invention, it is possible to deal with any combinations of parts/components in sealing feature.

### BRIEF DESCRIPTION OF THE DRAWINGS

Other objects and further features of the present invention will become more apparent from the following detailed description when read in conjunction with the following accompanying drawings:

FIG. 1 shows, in a magnified manner, a sectional view of a sealing device and a neighborhood thereof in an integrated fluid supply apparatus in the related art, wherein the sealing device is a metal gasket;

FIG. 2 shows, in a magnified manner, a sectional view of a sealing device and a neighborhood thereof in an integrated fluid supply apparatus in the related art, wherein the sealing device is a metal C ring;

FIG. 3 shows an elevational sectional view of a semiconductor manufacturing system in one embodiment of the present invention;

FIG. 4 shows a front elevational view of an integrated fluid supply apparatus (integrated gas supply apparatus) in one embodiment of the present invention:

FIG. 5 shows an exploded perspective view of the integrated fluid supply apparatus shown in FIG. 4;

FIG. 6 shows, in a magnified manner, an elevational sectional view of a part defined by a circle indicated as ‘A’ in FIG. 4;

FIG. 7 shows, in a magnified manner, an exploded elevational sectional view of a sealing device in a first embodiment of the present invention and a neighborhood thereof at a connection position between a gas processing unit and a base block of the integrated gas supply apparatus;

FIG. 8 shows, in a magnified manner, an elevational view of the sealing device and neighborhood thereof shown in FIG. 7 in an assembled state;

FIG. 9 shows a sectional view of the sealing device shown in FIG. 7;

FIG. 10 shows, in a magnified manner, an exploded elevational sectional view of a sealing device in a second embodiment of the present invention and a neighborhood thereof at a connection position between a gas processing unit and a base block of the integrated gas supply apparatus;

FIG. 11 shows, in a magnified manner, an elevational view of the sealing device and neighborhood thereof shown in FIG. 10 in an assembled state;

FIG. 12 shows a sectional view of the sealing device shown in FIG. 10;

FIG. 13 shows, in a magnified manner, an elevational sectional view of a sealing device in a variant embodiment of the second embodiment of the present invention and a neighborhood thereof in an assembled state at a connection position between a gas processing unit and a base block of the integrated gas supply apparatus; and

FIG. 14 shows a sectional view of the sealing device shown in FIG. 13.

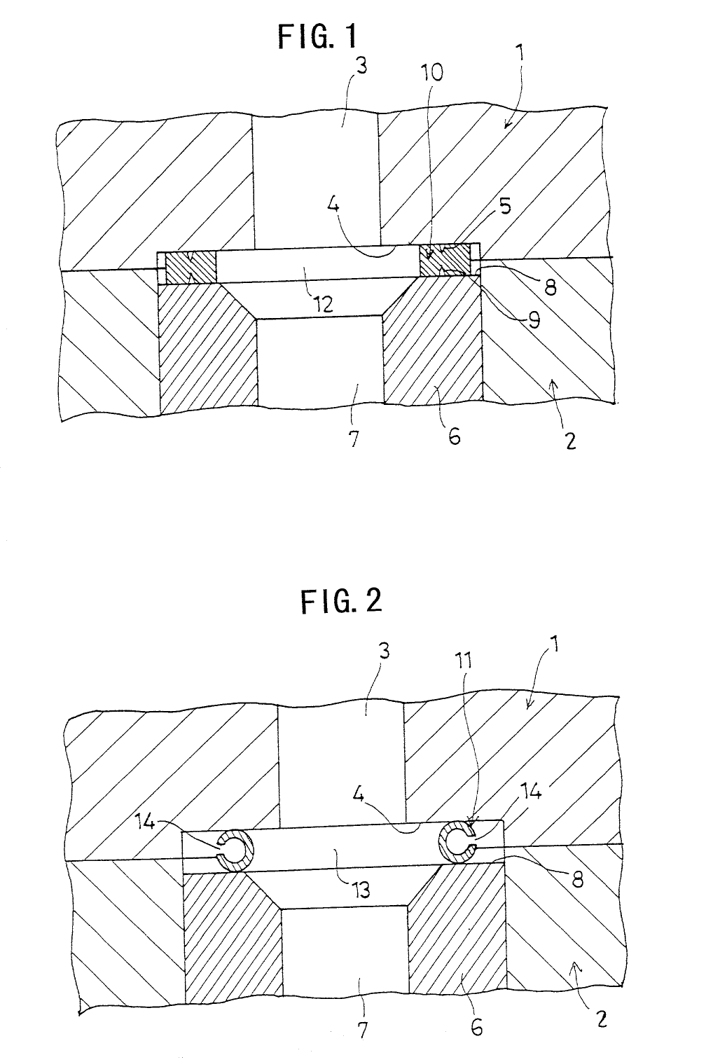

### DETAILED DESCRIPTION OF THE PREFERRED EMBODIMENT

Preferred embodiments of this invention will now be described with reference to figures.

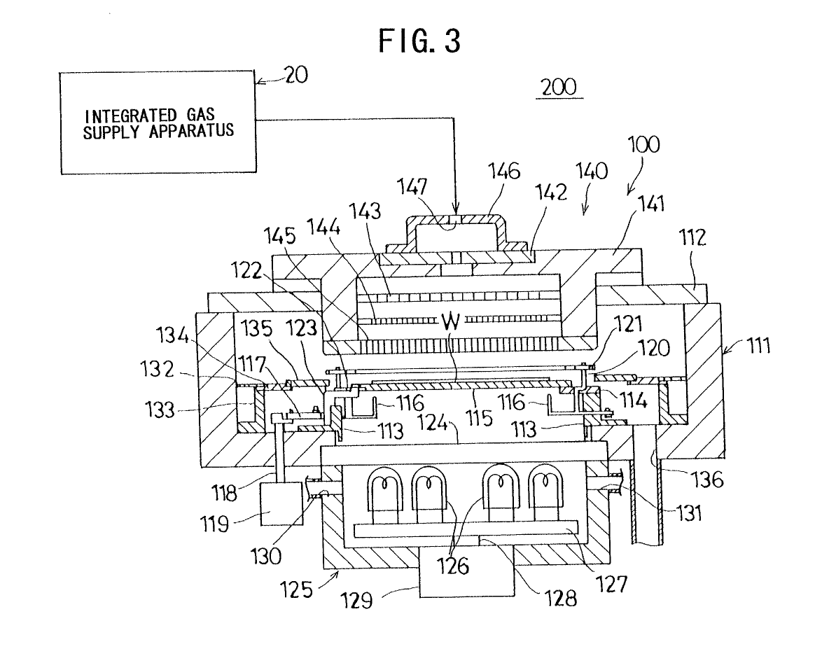

FIG. 3 shows a semiconductor manufacturing system 200 in one embodiment of the present invention. The semiconductor manufacturing system 200 is an example of a semiconductor manufacturing system in which a thin film is grown on a wafer through vapor phase epitaxy. This semiconductor manufacturing system includes an integrated gas supply apparatus 20 (integrated fluid supply apparatus) and a vapor phase epitaxy apparatus 100 (simply referred to as a CVD apparatus, hereinafter).

As shown in FIG. 3, the CVD apparatus 100 has a chamber 111 provided in a shape of a cylinder and made of aluminum, or the like, and a lid member 112 is provided thereon. In this chamber 111, on a support part 113 standing from the bottom of the chamber 111, a placement table 115 on which a wafer W is placed is provided via a holding member 114. The inner wall of the support member 113 has a provision such as to reflect heat rays, and, the placement table 115 is made of a carbon material, ceramic or the like having a thickness on the order of 2 mm.

For example, three lift pins 116 for lifting the wafer W from the placement table 115 are provided below the table 115, are supported by a pushing up rod 118 via a holding member 117, and this pushing up rod 118 is connected to an actuator 119. As the actuator 119 lifts or lowers the pushing up rod 118, the lift pins 116 are thus lifted or lowered, and, thus, the wafer W is lifted or lowered, accordingly.

These lift pins 116 are made of a material such as to transmit heat rays, for example, quartz. A support member 120 is integrally provided on the lift pins 116, and a shield ring 121 is mounted on the support member 120. This shield ring 121 has a function of preventing heat rays from halogen lamps 126, which will be described later, from being applied to the top of the chamber 111, and, also, securing a flow path of a cleaning gas at a time of cleaning the chamber.

A thermocouple 122 for measuring the temperature of the wafer W at a time of heating the wafer W is embedded in the placement table 115, and, a holding member for the thermocouple 122 is attached to the support member 113. Moreover, a transmission window 124 made of a material of transmitting heat rays, such as quartz, is provided at a bottom of the chamber 111 in an airtight manner just under the placement table 115, and a box-like heating room 125 is provided below it.

In this heating room 125, the four halogen lamps 126 are attached on a rotation stand 127 which serves also as a reflector, and this rotation stand 127 rotates by a rotary motor 129 provided in the bottom of the heating room 125 via a rotation shaft 128. Therefore, heat rays emitted from these halogen lamps 126 can pass the transmission window 124, can be applied to the undersurface of the placement table 115, and thereby can heat it. A cooling air entrance 130 for enabling a cooling air to enter the heating room 125 and a cooling air exit 131 for enabling the air to exit are provided in a side wall of the heating room 125, the cooling air cooling this room 125 and transmission window 124.

On the outer side of the placement table 115, a straightening plate 132 of a shape of a ring which has many straightening holes is laid on a cooling plate 134 provided at the top end of a support column 133 provided annularly. An attachment 135 made of quartz or aluminum and having a shape of a ring for preventing the processing gas from flowing from the top to the bottom of the chamber is provided on the inner side of this cooling plate 134. Under these straightening plate 132, cooling plate 134, and attachment 135, an inactive gas which does not react with the processing gas, for example, nitrogen gas etc., is supplied as a back side gas, and, thereby, the processing gas is prevented from entering under the placement table 115 and performing a problematic film forming function there.

Moreover, exhaust paths 136 are provided in the four corners of the bottom of the chamber 111, and the vacuum pump which is not shown is connected to these exhaust paths 136. Thereby, the inside of the chamber 111 can be kept in a vacuum condition, for example, on the order of 100 torrs through 10⁻⁶ torrs.

A shower head 140 for causing the processing gas etc. to enter the chamber is provided in a ceiling part of the chamber 111. This shower head 140 has a shower base 141 fitted in the lid member 112, and an orifice plate 142 which passes the processing gas etc. therethrough is provided at the center of an upper part of this shower base 141. Furthermore, two stages of diffusion plates 143 and 144 are provided below the orifice plate 142, and a shower plate 145 is provided below these diffusion plates 143 and 144. A gas entrance member 146 is provided above the orifice plate 142, and, a gas entrance 147 is provided at the top of the gas entrance member 145. The integrated gas supply apparatus 20 which supplies the processing gas etc. into chamber 111 is connected to this gas entrance mouth 147.

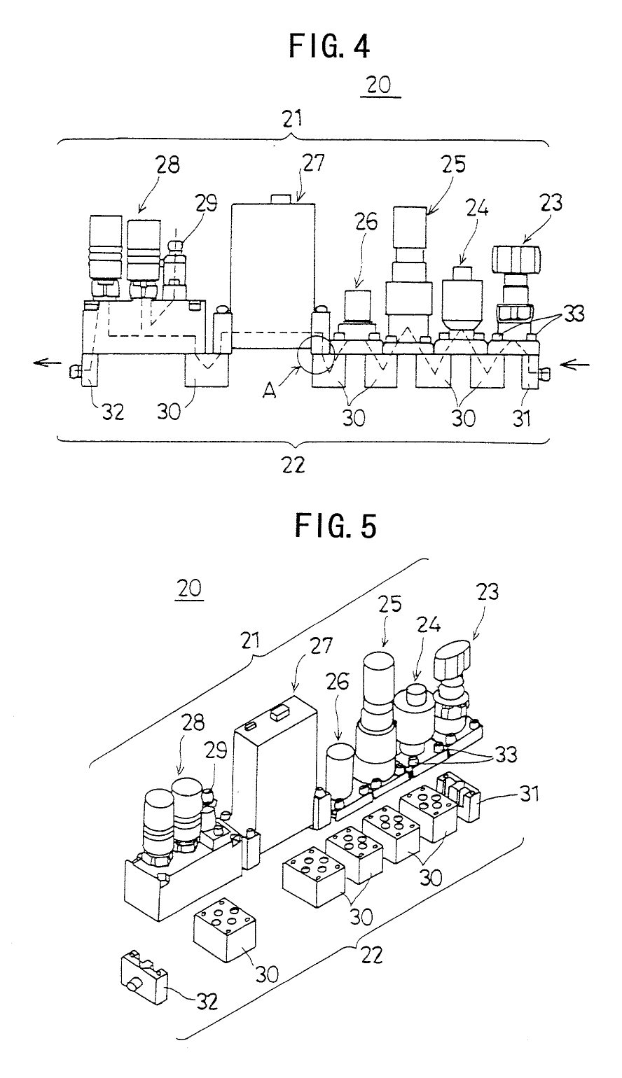

The integrated gas supply apparatus 20 in one embodiment of the present invention will now be described with reference to FIGS. 4 and 5. As mentioned above, this apparatus 20 is connected with the above-described CVD apparatus 100, and the integrated gas supply apparatus 20 supplies the semiconductor manufacture gas of high purity, career gas, etc. to the CVD apparatus 100 (these gases will be generically referred to as a semiconductor manufacture gas hereinafter).

Although a plurality types of semiconductor manufacture gases are usually supplied to the semiconductor manufacturing system and a plurality integrated gas supply apparatuses 20 are also arranged accordingly, only the single integrated gas supply apparatus 20 is shown and described for the sake of simplification of the description.

The integrated gas supply apparatus 20 in the embodiment of the present invention is configured so as to achieve an improvement in effective use of a clean room, fine flow control of the semiconductor manufacture gas, and substitution performance of the gas. Specifically, the apparatus is unified or be in a form of a unit. A specific configuration of the integrated gas supply apparatus 20 will now be described.

Roughly speaking, the integrated gas supply apparatus 20 includes an upper part 21 and a lower part 22. The upper part 21 includes various processing units which perform directly predetermined processing on the semiconductor manufacture gas. In the embodiment, the semiconductor manufacture gas flows from the right to the left in FIG. 4, and a manual valve 23, a pressure transducer 24, a regulator 25, a filter 26, a mass flow controller 27, and air operation valves 28 are disposed sequentially in a row from the upstream side with respect to the flow of the semiconductor manufacture gas.

The manual valve 23 is provided in order to control by manual operation a flow of the semiconductor manufacture gas which flows into the integrated gas supply apparatus 20. The pressure transducer 24 transudes the pressure of the semiconductor manufacture gas flowing into the integrated gas supply apparatus 20 into an electric signal and outputs it. The regulator 25 performs pressure adjustment for the semiconductor manufacture gas which flows into the integrated gas supply apparatus 20.

The filter 26 removes particles contained in the semiconductor manufacture gas. Together with the air operation valves 28, the mass flow controller 27 carries out automatic control of supply of the semiconductor manufacture gas to the CVD apparatus 100. A check valve 29 is attached to the air operation valves 28, and, thereby, the air in the air operation valves 28 is prevented from flowing backwards.

As will be described later, sealing devices 50A or 50B according to the present invention may be applied to any one of the above-mentioned manual valve 23, the pressure transducer 24, regulator 25, filter 26, mass flow controller 27, and air operation valves 28. Therefore, in the following description, when making description without specifying each of above-mentioned components (the manual valve 23, pressure transducer 24, regulator 25, filter 26, mass flow controller 27, and air operation valves 28) included in the upper part 21, the description is made in a manner such that the component is referred to as a ‘gas processing unit 40’ as a generic name, without particularly mentioning each specific name.

The lower part 22 includes a plurality base blocks 30 for middle parts, a base block 31 for inflow, and a base block 32 for an outflow. These base blocks 30 for middle parts, the base block 31 for inflow, and the base block 32 for outflow will be referred to genetically as base block(s) 30-32.

The base block 31 for inflow is provided at an inflow position of the semiconductor manufacture gas of the integrated gas supply apparatus 20, and, specifically, is disposed below the manual valve 23. This base block 31 for inflow is connected to a supply source (not shown) of the semiconductor manufacture gas.

The base block 32 for outflow is provided at an outflow position of the semiconductor manufacture gas of the integrated gas supply apparatus 20, and, specifically, is disposed below the air operation valve 28. This base block 32 for outflow is connected to the CVD apparatus 100, or another gas processing apparatus which performs predetermined processing on the semiconductor manufacture gas for a CVD film formation process or the like.

A gas passage 41 is provided inside of each base block 30 for middle parts, and has a function of connecting adjacent ones of the gas processing units 40 disposed in the row. Thereby, the semiconductor manufacture gas flows in the integrated gas supply apparatus 20 as shown by broken lines shown in FIG. 4.

These base blocks 30 for middle parts are arranged below the respective gas processing units 40, and, thereby, integrated gas supply apparatus 20 is unified. Therefore, compared with a gas supply apparatus having a configuration of connecting respective gas processing units using joints, pipes, sealing devices, etc. as in the related art, the entirety of the integrated gas supply apparatus 20 unified using the base blocks 30 for middle parts can be effectively miniaturized.

The gas processing units 40 and the base blocks 30-32 are fixed with each other by bolts 33, and it is needed to prevent leakage of the semiconductor manufacture gas at the connection positions between these gas processing units 40 and the base blocks 30-32. For this purpose, the sealing devices 50A are inserted between the gas processing units 40 and the base blocks 30-32.

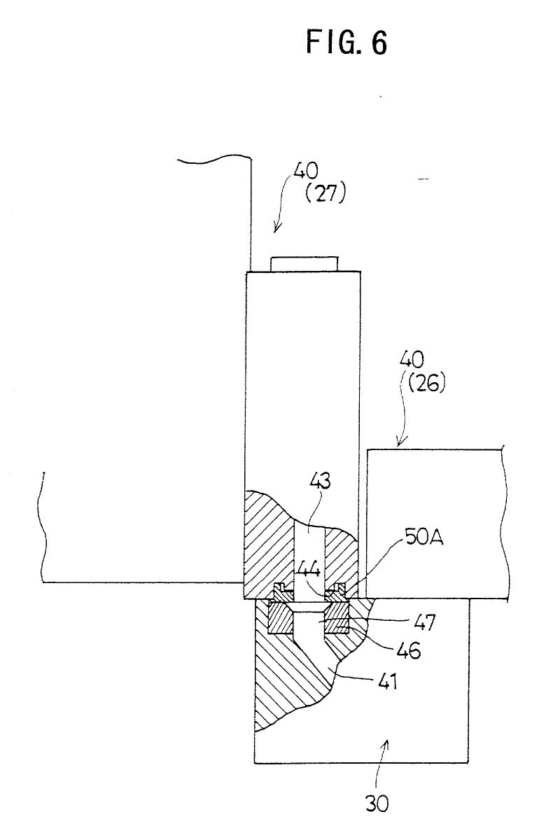

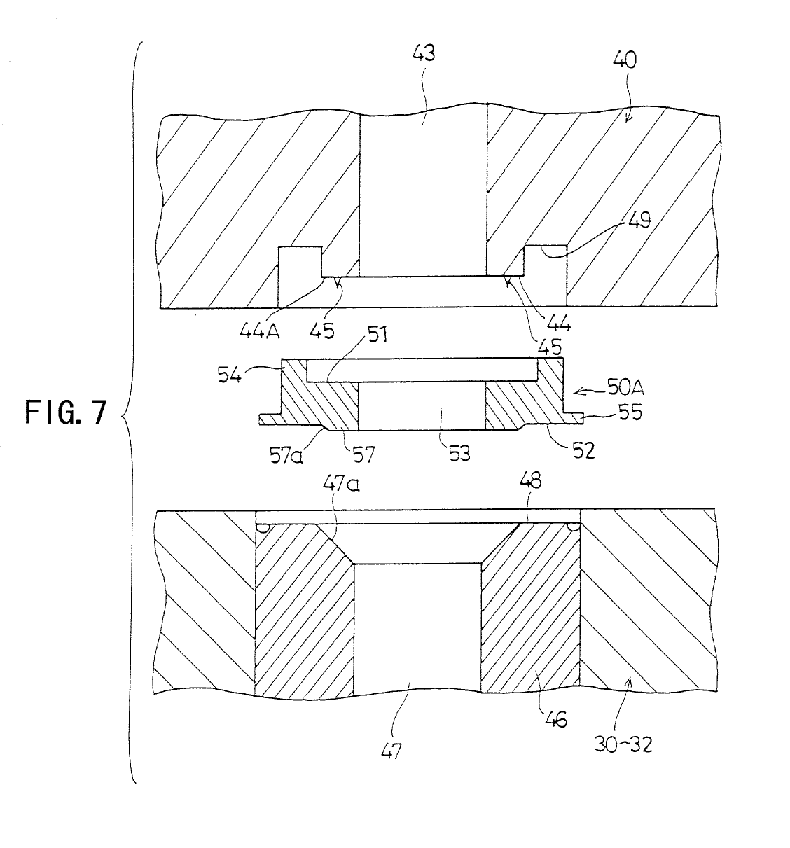

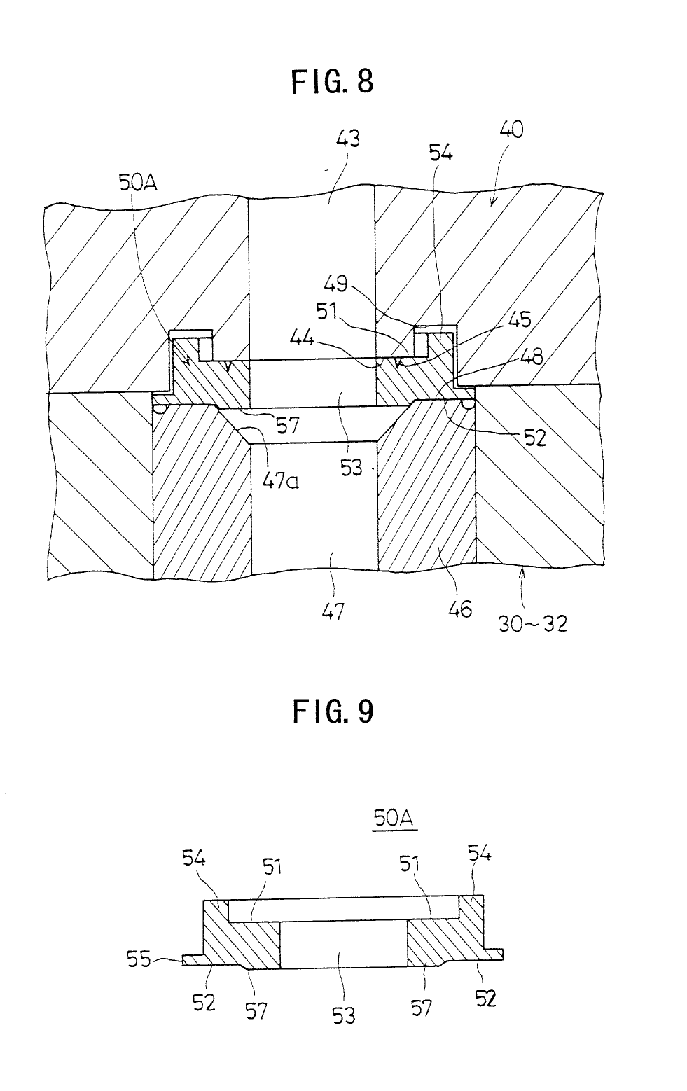

With reference FIGS. 6 through 9, sealing configuration using the sealing devices 50A between the gas processing units 40 and the base blocks 30-32 will now be described. FIG. 6 shows, in a magnified manner, a portion in FIG. 4 defined by a circle indicated by an arrow A. FIGS. 7 and 8 show, in a magnified manner, arrangement position of the sealing device 50A. FIG. 9 shows, in a magnified manner, the sealing device.

As shown in FIG. 6, a gas passage 41 is formed inside of each middle-part base block 30, and, on both ends thereof, block-side connection mouths 47 are provided (FIG. 6 only showing one side). Further, although not shown, each of the base block 31 for inflow and the base block 32 for outflow also has a similar configuration. This block-side connection mouth 47 includes, as shown in FIGS. 7 and 8, an opening on the block-side sealing surface 48 (block-side connection surface) formed in the top surface of a passage member 46.

This passage member 46 has a high sealing performance, and, as will be described later, is connected to a unit-side connection mouth 43 provided in the gas processing unit 40 (mass flow controller 27 in the case of the figure) through the sealing device 50A. This unit-side connection mouth 43 is configured such as to have an opening on a unit-side sealing surface 44 (unit-side connection surface) provided in a bottom surface of the gas processing unit 40 There, the configuration of the block-side sealing surface 48 provided in each of the base blocks 3032 and the unit-side sealing surface 44 provided in each gas processing unit 40 will now be compared. As shown in FIGS. 7 and 8, the block-side sealing surface 48 provided on the passage member 46 of the base block 30-32 has a flat surface. That is, the block-side sealing surface 48 provided in each of the base blocks 30-32 has a configuration such as to be suitable for the above-mentioned metal C ring.

On the other hand, the unit-side sealing surface 44 provided in each gas processing unit 40 is configured such as to have a sealing projection 45 projecting therefrom. That is, the unit-side sealing surface 44 provided in each gas processing unit 40 has a configuration such as to be suitable for the above-mentioned metal gasket.

Accordingly, in the combination between the sealing surfaces 44 and 48 in this embodiment, if the metal C ring in the related are were used, although the sealing performance with the block-side sealing surface 48 (base block 30) could be attained properly, it could not be possible to attain a sufficient sealing performance with the unit-side sealing surface 44. Furthermore, in the combination between the sealing surfaces 44 and 48 in this embodiment, if the metal gasket in the related art were used, although the sealing performance with the unit-side sealing surface 44 could be attained properly, it could not be possible to attain a sufficient sealing performance with the block-side sealing surface 48 (base block 30).

Thus, the sealing device 50A in the embodiment is configured such that, even when the sealing feature of the unit-side sealing surface 44 (gas processing unit 40) differs from the sealing feature of the block-side sealing surface 48 (base block 30-32) as mentioned above, the sealing device 50A can provide sufficient sealing performance in use therewith. The configuration of the sealing device 50A will now be described.

The sealing device 50A is approximately ring-shaped, and, for example, is made of stainless steel. A gas passage 53 through which the semiconductor manufacture gas passes this sealing device 50A is provided at the center thereof. Also, a rim part 55 extending outwards is provided at the bottom on the outer circumferential surface of the sealing device 50A.

Moreover, a first sealing surface 51 is provided on the top side of the sealing device 50A which will face the gas processing unit 40, and an annular projection part 54 is provided in the periphery of the first sealing surface 51. Furthermore, a second sealing surface 52 is provided on the bottom side of the sealing device 50A which will face the base block 30-32, and, an annular engagement projection part 57 projecting downward is provided in the central part of the second sealing surface 52.

The first sealing surface 51 has a feature such as to be suitable for the sealing feature of the unit-side sealing surface 44 (gas processing unit 40). Specifically, in a condition in which the gas processing unit 40 and the base block 30-32 are fixed to one another, the sealing projection 45 provided on the unit-side sealing surface 44 sticks into the first sealing surface 51 of the sealing device 50A.

The second sealing surface 52 is configured such as to be suitable for the sealing feature of the block-side sealing surface 48 (base block 30-32). Specifically, the block-side sealing surface 48 has a flat surface having a high-accuracy smoothness as being suitable for the above-mentioned metal C ring, and the second sealing surface 52 also has a flat surface having a high-accuracy smoothness corresponding thereto. Therefore, in a state where the gas processing unit 40 and the base block 30-32 are fixed to one another, the second sealing surface 52 and the block-side sealing surface 48 are stuck on one another tightly without any gap, and thus can perform high sealing performance.

If employing the metal C ring, as shown in FIG. 2, the metal C ring 11 and each sealing surfaces 4 and 8 would come into approximately a line contact, and thus, there would be a problem in that a sealing area (contact area) would be not sufficiently wide, and, thus, sufficient sealing performance could not be provided, depending on the operating condition of the integrated gas supply apparatus. In contrast thereto, by employing the sealing device 50A in the embodiment of the present invention, since the block-side sealing surface 48 and the second sealing surface 52 can be in contact with one another in an effective area contact manner positively, the sealing area can be effectively increased and, therefore, can aim at improvement in the sealing performance at the connection position.

When using the sealing device 50A between the base block 30-32 and gas processing unit 40 at the connection position, the sealing device 50A is inserted therebetween as shown in FIG. 7. Under this condition, the annular projection part 54 provided on the upper surface of sealing device 50A faces an annular depression part 49 provided in the gas processing unit 40. Further, an outer edge of the annular engagement projection part 57 provided on the bottom surface of the sealing device 50A has a tapered surface 57a which is fitted with a tapered surface 47a formed in the block-side connection mouth 47 of the base block 30-32, as shown in FIGS. 7 and 8.

Accordingly, when the sealing device 50A is loaded into the base block 30-32, the engagement projection part 57 is inserted into the block-side connection mouth 47. Thereby, the loading position of the sealing device 50A into the base block 30 can be easily determined. Moreover, positioning of the sealing device 50A onto the gas processing unit 40 can be easily performed by engaging the annular projection part 45 with the annular depression part 49 of the gas processing unit 40. Therefore, operation of loading the sealing device 50A between the base block 30-32 and gas processing unit 40 can be performed easily.

After the sealing device 50A is inserted between the base block 30-32 and gas processing unit 40 as mentioned above, the base block 30-32 and gas processing unit 40 are fixed to one another by the bolts 33 (see FIGS. 4 and 5). Thereby, the sealing projection 45 provided on the unit-side sealing surface 44 sticks into the first sealing surface 51 of the sealing device 50A, and sealing at the connection position between the unit-side sealing surface 44 of the gas processing unit 40 and the first sealing surface 51 is performed with high sealing performance. Simultaneously, the second sealing surface 52 and the block-side sealing surface 48 are firmly and tightly stuck onto one another as described above, and, therefore, sealing also at the connection position between the second sealing surface 52 and the block-side sealing surface 48 is performed with high sealing performance.

Thus, even when the sealing feature of the base block 30-32 differs from the sealing feature of the gas processing unit 40 as mentioned above, by employing the sealing device 50A in the embodiment of the present invention, it is possible to connect the gas processing unit 40 with the base block 30-32 positively properly. Thereby, it is possible to freely select a combination between the base block 30-32 (including the base blocks for middle parts, base block 31 for inflow, and base block 32 for outflow) and gas processing unit 40, by adding the sealing device according to the present invention to the metal gaskets/metal C rings in the related art as usable sealing devices, and, thereby, improvement in the performance of the integrated gas supply apparatus 20 and cost reduction can be attained.

A second embodiment of the present invention will now be described.

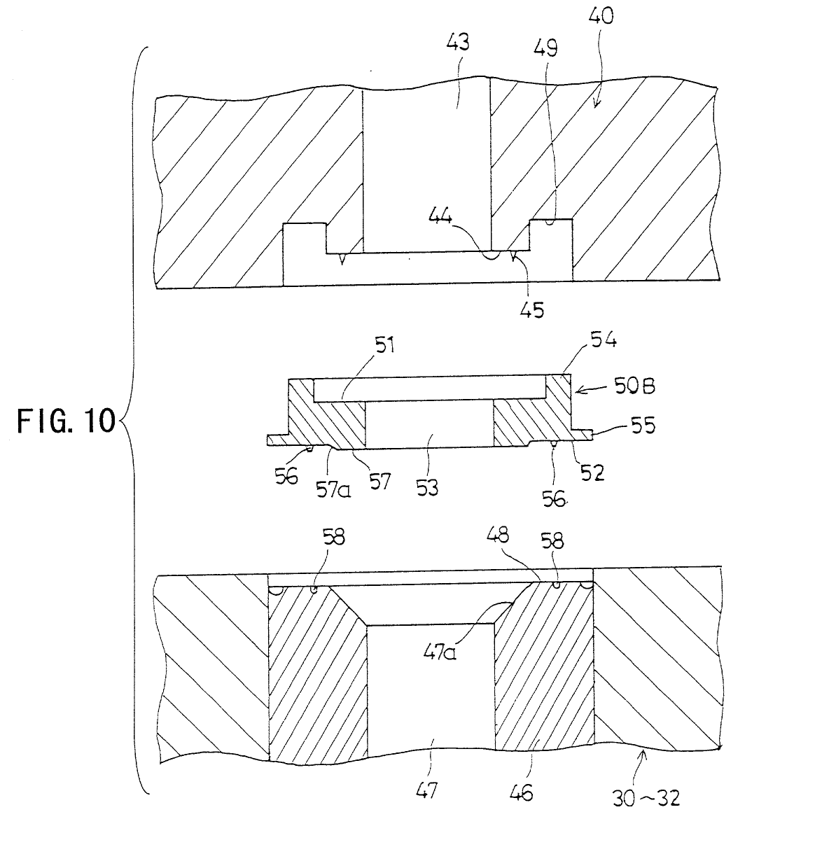

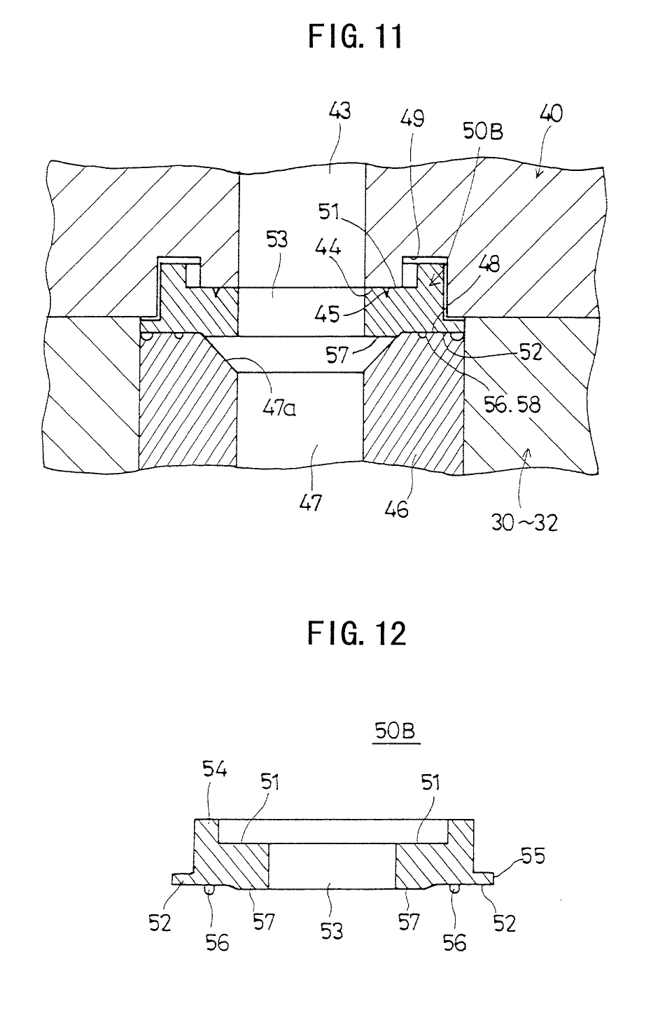

FIGS. 10 through 12 illustrate the second embodiment of the present invention. FIGS. 10 and 11 show, in a magnified manner, the sealing device 50B in the second embodiment and a neighborhood thereof. FIG. 12 shows, in a magnified manner, the sealing device SOB alone. In FIGS. 10 through 12, for the same parts/components as those in the above-described first embodiment described with reference to FIGS. 4 through 9, the same reference numerals are given, and the duplicated description thereof is omitted.

In the second embodiment, a positioning projection 56 is formed on a second sealing surface 52 of the sealing device 50B, and a positioning groove 58 is formed in a block-side sealing surface 48 accordingly.

The positioning groove 58 is a groove annularly formed in the block-side sealing surface 48. The positioning projection 56 is a projection annularly formed on the second sealing surface 52 of the sealing device 50B, and the position thereof is such as to correspond to the position of the positioning groove 58.

Therefore, when the sealing device 50B is loaded onto the base block 30-32, positioning of the sealing device 50B with the base block 30-32 is determined by engagement between the engagement projection part 57 and block-side connection mouth 47 (tapered surface 47a), and, also, by engagement between the positioning projection 56 and the positioning groove 58. Thereby, it is possible to position the sealing device 50B with respect to the base block 30-32 at a high precision.

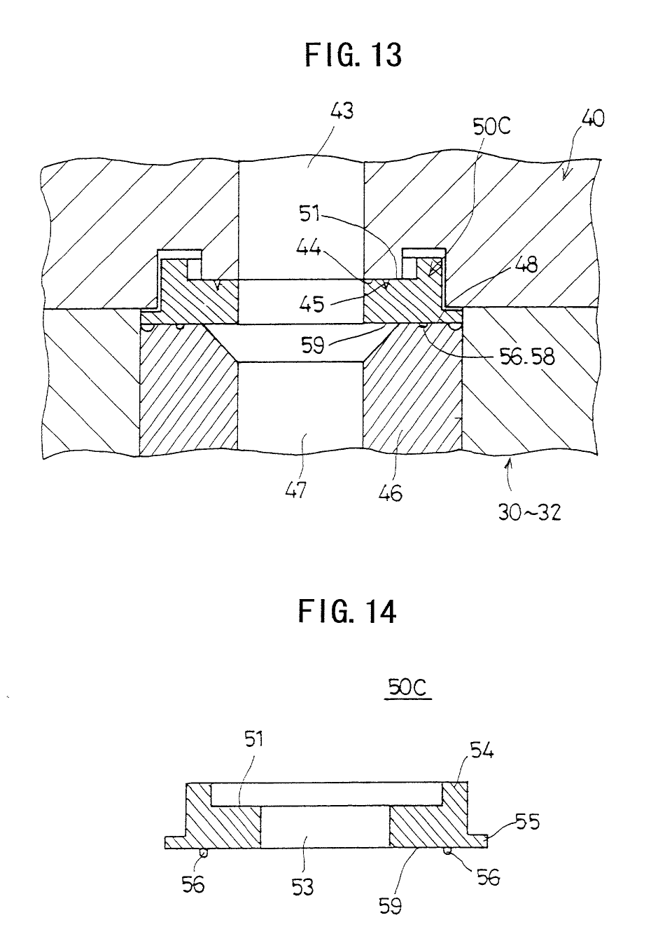

FIGS. 13 and 14 show a variant embodiment of the above-described second embodiment. A sealing device 50C in the variant embodiment of the second embodiment has a feature in that a second sealing surface 59 only has a simple flat surface with no engagement projection part 57 formed thereon.

Therefore, in the configuration of the variant embodiment of the second embodiment, positioning of the sealing device 50C with respect to the base block 30-32 is performed only by engagement between the positioning projection 56 and the positioning groove 58. Depending on a particular form/type at the connection position (for example, the size of the sealing device, and so forth), positioning of the sealing device 50C with respect to the base block 30-32 can be sufficiently performed only by the engagement between the positioning projection 56 and the positioning groove 58. In such a case, simplification in configuration of the sealing device SOC and reduction of working cost can be aimed at, and thus, cost reduction of the sealing device 50C can be attained.

In addition, in each of the above-mentioned embodiments, the sealing feature of the gas processing unit 40 is that suitable for the metal gasket, and the sealing feature of the base block 30-32 is that suitable for the metal C ring, for example. However, even in a case where, for example, the sealing feature of the gas processing unit 40 is that suitable for the metal C ring and the sealing feature of the base block 30-32 is that suitable for the metal gasket, it is possible to apply the present invention in a similar manner.

Moreover, although each of the above-mentioned embodiments is an embodiment in which the sealing device 50A, 50B or SOC according to the present invention is applied to the integrated gas supply apparatus 20, application of the sealing device according to the present invention is not limited to one to the integrated gas supply apparatus 20. For example, the present invention can also be applied to a sealing part between a top electrode of a process chamber and a wall, and a sealing part between a bottom electrode and a wall thereof, for example. Furthermore, the present invention can also be applied to a sealing part between a top lid and a wall in a load lock chamber, and a sealing part between a bottom lid and a wall thereof, for example. Thus, a sealing device according to the present invention may be widely applied to a sealing part between a vacuum-pressure space and an atmospheric-pressure space but having no movable portion.

Further, the present invention is not limited to the above-described embodiments, and variations and modifications may be made without departing from the scope of the present invention.

The present application is based on Japanese priority application No. 2000-323057, filed on Oct. 23, 2000, the entire contents of which are hereby incorporated by reference.

What is claimed is:

1. An integrated fluid supply apparatus comprising:
fluid processing units each performing predetermined processing on a fluid supplied via a unit-side fluid connection mouth provided in a unit-side connection surface thereof;
a flow path block having block-side connection mouths on a block-side connection surface thereof to be connected with the unit-side fluid connection mouths, and, as being disposed below said fluid processing units, communicating the unit-side connection surfaces of the adjacent fluid processing units; and
sealing devices each inserted between said unit-side fluid connection mouth and said block-side connection mouth, and, thus, performing sealing between said unit-side connection surface and said block-side connection surface at a connection position therebetween;
wherein at least one of said sealing devices comprises a first connection surface configured to be suitable to a first sealing feature of said unit-side connection surface and a second connection surface configured to be suitable to a second sealing feature of said block-side connection surface, said first sealing feature being different from said second sealing feature.

2. The integrated fluid supply apparatus as claimed in claim 1, wherein:
said first sealing feature is for a metal gasket, while said second sealing feature is for a metal C ring.

3. The integrated fluid supply apparatus as claimed in claim 1, wherein:
at least said block-side connection surface and said second connection surface are configured such that connection therebetween be in an effective area contact.

4. A sealing device to be inserted between a unit-side fluid connection surface of a fluid processing unit and a block-side connection surface of a flow path block, and providing a sealing performance therebetween while a fluid passes therethrough between said fluid processing unit and flow path block, comprising:
a first connection surface configured to be suitable to a first sealing feature of said unit-side connection surface; and
a second connection surface configured to be suitable to a second sealing feature of said block-side connection surface,
said first sealing feature being different from said second sealing feature.

5. The integrated fluid supply apparatus as claimed in claim 4, wherein:
said first sealing feature is for a metal gasket, while said second sealing feature is for a metal C ring.

6. The integrated fluid supply apparatus as claimed in claim 4, wherein:
at least said block-side connection surface and said second connection surface are configured such that connection therebetween be in an effective area contact.

7. A semiconductor manufacturing system comprising:
a substrate processing apparatus performing predetermined processing on a substrate by supplying a predetermined fluid thereto; and
the integrated fluid supply apparatus claimed in claim 1 supplying the predetermined fluid to said substrate processing apparatus.
